(19) United States
(12) Patent Application Publication
(10) Pub. No.: US 2015/0128849 A1
(43) Pub. Date: May 14, 2015

(54) CRUCIBLE FOR THE MANUFACTURE OF OXIDE CERAMIC SINGLE CRYSTALS

(71) Applicant: PLANSEE SE, REUTTE (AT)

(72) Inventors: Judith Januschewsky, Reutte (AT); Heike Larcher, Bach (AT); Manfred Sulik, Reutte (AT)

(73) Assignee: PLANSEE SE, REUTTE (AT)

(21) Appl. No.: 14/395,147

(22) PCT Filed: Apr. 16, 2013
(86) PCT No.: PCT/AT2013/000074

§ 371 Date: Oct. 17, 2014

Related U.S. Application Data
(60) Provisional application No. 61/625,296, filed on Apr. 17, 2012.

(51) Int. Cl. C30B 11/00; B05D 7/22; C30B 29/20

(52) U.S. Cl. CPC C30B 11/002; C30B 29/20; B05D 7/22
USPC 117/81; 117/223; 427/236

(57) ABSTRACT

A crucible made of molybdenum or a molybdenum alloy having a molybdenum content of more than 95 at % for producing an oxide-ceramic single crystal. The inner side of the crucible is at least partially provided with a layer that contains at least one refractory metal and is formed with pores.

The invention relates to a crucible made of molybdenum or a molybdenum alloy having a molybdenum content of more than 95 at %, to a method for its production and to a method for producing sapphire single crystals.

Oxide-ceramic single crystals, for example sapphire single crystals, are produced inter alia in crucibles made of molybdenum. Single-crystal sapphire substrates are used, for example, for the epitaxial deposition of gallium nitride, which is widely employed for the production of LEDs and particular semiconductor lasers. Various methods for pulling oxide-ceramic single crystals are known, for example HEM (Heat Exchange Method), Kyropoulos and EFG (Edge defined Film-fed Growth).

The costs of the crucible represent a significant proportion of the total costs, since the crucible is usually broken when the solidified single crystal is removed therefrom. The reasons for this are excessive adhesion between solidified oxide melt and the crucible, combined with high brittleness of molybdenum caused by recrystallization and grain growth.

DE 10 2008 060 520 A1 describes a crucible and a method for processing a material with a high melting point in this crucible, that part of the surface of the crucible which comes in contact with the melt of the material with a high melting point being covered with a foil that consists of a metal having a melting point of at least 1800° C. If a material-fit connection between the foil and the crucible is not formed, the thermal transmission can be locally degraded, which in turn has a detrimental effect on precise adjustment of the temperature profile.

It is an object of the present invention to provide a crucible for crystal growth, a method for crucible production and a method for sapphire single crystal growth with such a crucible, with which the costs expended on the crucible for the sapphire single crystal growth can be reduced.

The object is achieved by a crucible, the inner side of which is at least partially provided with a layer that contains at least one refractory metal selected from the group consisting of tungsten and molybdenum and comprises pores. The porosity is preferably >5 vol %. A porosity from the group >10 vol %, >15 vol %, >20 vol % and >25 vol % is particularly preferably selected. Furthermore, the pores are preferably at least partially connected to one another, which is referred to as open porosity. The crucible according to the invention is particularly suitable for the production of oxide-ceramic single crystals, for example sapphire single crystals.

In the description below, tungsten, molybdenum and tungsten/molybdenum alloys are sometimes mentioned individually, or are referred to together as refractory metal. The term refractory metal therefore covers tungsten, molybdenum and tungsten/molybdenum alloys throughout the entire mixing range.

The porosity of the layer leads to a very high bonding strength between the layer and the single crystal pulled in the crucible, since the aluminum oxide melt penetrates into the pores and therefore, after solidification, also leads to mechanical micro-dovetailing effects in addition to chemical/physical mechanisms. The layer according to the invention, conversely, has lower adhesion to the molybdenum crucible. The bonding strength between the crucible and the layer may in this case also be influenced favorably—i.e. so as to be reduced—by a further layer, which reduces diffusion processes between the refractory metal layer and the crucible. When the single crystal is being removed from the crucible, the weak point in the crucible/layer/oxide system is the interface between the crucible and the layer. The single crystal can be removed relatively easily from the crucible with at least parts of the adhering layer. The crucible can therefore be reused at least once.

The refractory metal content in the layer is advantageously more than 50 ma %. A refractory metal content from the group >75 ma %, >90 ma %, >95 ma % and >99 ma % is preferably selected. A layer of pure tungsten is particularly preferably used, since tungsten has the highest resistance to aluminum oxide melts. The layers according to the invention therefore have high resistance to most oxide-ceramic melts, in particular to aluminum oxide melts.

The refractory metal preferably forms a continuous skeletal structure. The upper limit for the advantageous porosity of the layer is 60 vol %. In the case of a porosity of more than 60 vol %, the advantageous skeletal structure can only be formed with high process outlay. It is furthermore advantageous for the layer to be configured with very fine grains, and for the grain size to lie in the range of from 0.1 to 5 μm. Undesired crystal seed formation of the aluminum melt in the region of the crucible wall is thereby avoided.

For the production of sapphire single crystals, in addition to the refractory metal, the layer may also contain aluminum oxide, since this does not detrimentally affect the purity of the sapphire. Composite materials containing aluminum oxide are highly suitable for the production of sapphire single crystals because the aluminum oxide of the composite material melts during use and, upon solidification, forms a dovetailed network with the aluminum oxide of the sapphire, which leads to excellent bonding between the layer and the sapphire single crystal. It is advantageous for the refractory metal to form a continuous skeletal structure, which limits the aluminum oxide content preferably to 60 vol %.

The layer therefore advantageously comprises the following materials: pure molybdenum, pure tungsten, molybdenum/tungsten alloys throughout the composition range, molybdenum/aluminum oxide composite materials, tungstenaluminum oxide composite materials, and molybdenum/tungsten/aluminum oxide composite materials.

Furthermore, the layer preferably has a layer thickness of from 5 to 400 μm, particularly preferably from 10 to 200 μm. Thick layers have poor layer bonding in relation to the molybdenum crucible, so that the separation process is facilitated.

For the process management, it is furthermore advantageous for the crucible to have a relative density >99%, particularly preferably >99.5%.

The object of the invention is furthermore achieved by a method for producing a crucible.

First, preferably, a plate of molybdenum or a molybdenum alloy with a molybdenum content >95 wt % is produced and is shaped by pressure rolling to form a crucible. The crucible therefore has a density >99.5%. In particular, slurry methods and spray methods, for example plasma spraying, are suitable for the deposition of the layer. A slurry is in this case intended to mean a suspension that contains at least powder particles and a liquid. It is advantageous for the slurry to contain at least one powder selected from the group tungsten, molybdenum and aluminum oxide, as well as a binder and a readily evaporable liquid. If slurry deposition is used, it is advantageous for the slurry to be applied by spraying, pouring, brushing or rolling. The particle size of the powder, measured according to Fisher, is advantageously from 0.1 to 5 μm. An advantageous refractory metal content in the slurry is from 55 to 85 ma %.

As examples, cellulose esters may be mentioned for a suitable binder, and nitrocellulose thinner for the readily evaporable liquid. After application of the slurry, it is advantageous for the crucible to be annealed at a temperature of from 1200 to 2000° C. This leads to sintering between the individual grains and formation of the advantageous structure, but without an excessive bonding strength being established between the crucible and the layer.

The layer deposition may, for example, also be carried out by the spray methods commercially available for refractory metals, for example flame spraying and plasma spraying.

With this method, it is straightforwardly and economically possible to deposit the layer according to the invention. The layer in this case preferably has a porosity P of 5 vol %<P<60 vol %. Particularly preferably, the porosity P is 10 vol %<P<40 vol %.

The object of the invention is furthermore achieved by a method for producing a sapphire single crystal. HEM (Heat Exchange Method) is particularly preferably used in this case.

The method comprises the following steps. First, a crucible made of molybdenum or a molybdenum alloy having a molybdenum content of more than 95 at % is produced. This may, for example, be done by pressure rolling of a metal plate. The inner side of the crucible is then provided at least partially with a layer that contains at least one refractory metal selected from the group consisting of tungsten and molybdenum and comprises pores. A porosity of more than 5 vol % is preferably established. The layer production is preferably carried out by one of the methods described above, the layer preferably having at least one of the properties presented above.

Aluminum oxide is then introduced into the crucible and melted. The production of the sapphire single crystal is carried out by controlled cooling, for example starting with a seed crystal. When the single crystal is removed from the crucible, the layer is at least partially separated from the crucible. Since the mechanical stresses on the brittle molybdenum crucible are therefore low, the crucible is not broken by this process. The crucible can therefore be reused at least once.

The layer production is explained below with reference to a W layer.

The coating material for the W spray coating is based on a tungsten suspension, which contains cellulose nitrate. The batch preparation of the W slurry was carried out with the aid of a dispenser. In this case, the W powder with a Fisher grain size of 0.6 μm was mixed portion-wise at a rotational speed of 5000 rpm with the cellulose nitrate (15 ma %) and the combination nitrocellulose thinner (15 ma %). The application was carried out by means of spraying.

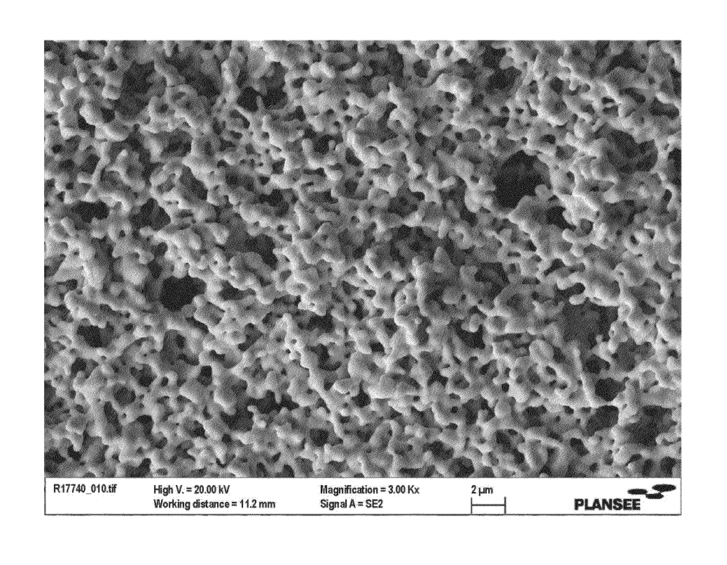

After the layer had been applied, it was annealed at 1450° C./2h. The layer has a high porosity of 35 vol % (see FIG. 1). The porosity measurement may be carried out by means of mercury porosimetry or buoyancy methods, using paraffin, according to the conventional specifications.

1-16. (canceled)

17. A crucible, comprising:
a crucible body made of molybdenum or a molybdenum alloy having a molybdenum content of more than 95 at %;
a layer formed on at least part of an inner side of said crucible body, said layer containing at least one refractory metal selected from the group consisting of tungsten and molybdenum and being formed with pores.

18. The crucible according to claim 17, wherein said layer has a porosity of more than 5 vol %.

19. The crucible according to claim 17, wherein said layer contains tungsten.

20. The crucible according to claim 17 configured for the production of oxide-ceramic single crystals.

21. The crucible according to claim 17, wherein said layer has a layer thickness of from 5 to 400 μm.

22. The crucible according to claim 17, wherein said layer has a porosity of less than 60 vol %.

23. The crucible according to claim 17, wherein said layer has a grain size of from 0.1 to 5 μm.

24. The crucible according to claim 17, wherein said layer contains at least 50 ma % of refractory metal.

25. The crucible according to claim 24, wherein said layer contains at least 95 ma % of the refractory metal.

26. The crucible according to claim 17, wherein said layer contains aluminum oxide.

27. The crucible according to claim 17, wherein said layer consists of a composite material of refractory metal and aluminum oxide.

28. The crucible according to claim 17, wherein said layer has the characteristics of a layer having been deposited by a slurry method or a spray method.

29. A method for producing a crucible, the method comprising:
providing a crucible body made of molybdenum or a molybdenum alloy having a molybdenum content of more than 95 at %;
forming a porous layer on at least part of an inner side of the crucible body by way of a slurry method or a spray method, the layer containing at least one refractory metal selected from the group consisting of tungsten and molybdenum.

30. The method according to claim 29, wherein the step of forming the layer comprises applying a slurry that contains at least one powder selected from the group consisting of tungsten, molybdenum and aluminum oxide, a binder and a readily evaporable liquid.

31. The method according to claim 30, which comprises setting the refractory metal content in the slurry to between 55 and 85 ma %.

32. The method according to claim 29, which comprises, after applying the slurry, annealing the crucible at a temperature of from 1200 to 2000° C.

33. A method for producing sapphire single crystals, the method comprising the following production steps:
producing a crucible made of molybdenum or a molybdenum alloy having a molybdenum content of more than 95 at %, an inner side of the crucible being at least partially provided with a layer containing at least one refractory metal selected from the group consisting of tungsten and molybdenum and having pores formed therein;
introducing aluminum oxide into the crucible and melting the aluminum oxide in the crucible;
carrying out a controlled cooling and production of the sapphire single crystal;
removing the sapphire single crystal from the crucible; and
reusing the crucible to produce at least one further sapphire single crystal.
